(19) United States
(12) Patent Application Publication
(10) Pub. No.: US 2003/0072575 A1
(43) Pub. Date: Apr. 17, 2003

(54) Method and apparatus for conveying a workpiece through a workstation and specifically for conveying a lithographic printing plate through a developing station and for applying a developer solution

(75) Inventors: Howard A. Fromson, Stonington, CT (US); William J. Rozell, Vernon, CT (US)

Correspondence Address: ALIX YALE & RISTAS LLP, 750 MAIN STREET, SUITE 1400, HARTFORD, CT, 06103, US

(73) Assignee: Howard A. Fromson

(21) Appl. No.: 10/154,573

(22) Filed: May 24, 2002

Related U.S. Application Data
(63) Continuation-in-part of application No. 10/137,967, filed on May 3, 2002, now abandoned.
Application No. 10/137,967 is a continuation-in-part of application No. 09/975,165, filed on Oct. 11, 2001, now abandoned.

(51) Int. Cl. G03F 7/30; G03F 7/00

(52) U.S. Cl. 396/611; 430/302; 430/309; 430/325

(57) ABSTRACT

A method and apparatus for conveying a thin, planar, flexible work piece through a work station with the work piece being held flat as it is conveyed. Specifically, a method and apparatus for developing an imaged coating on a lithographic printing plate involves the application of a thin film of developer solution to the imaged coating and allowing time for the dissolution to take place as the plate is conveyed through the developer across a flat horizontal platen. The spent developer solution is then removed and discarded to waste. Therefore, fresh developer solution of the proper composition is always being used to develop each plate. A film of water between the plate and the conveyor belt holds the plate in position and flat on the conveyor. The fresh developer solution is stored and delivered out of contact with the atmosphere to prevent atmospheric-caused degradation.

This application is a continuation-in-part of U.S. application Ser. No. 10/137,967 filed May 3, 2002 which is a continuation-in-part of U.S. application Ser. No. 09/975,165 filed Oct. 11, 2001, both of which are titled “Developing Imaged Lithographic Printing Plates”.

The present invention is directed to a method and apparatus for conveying planar, flexible work pieces through a workstation and specifically for conveying lithographic printing plates through a developing station and for storing and delivering the developer solution to the plates.

### BACKGROUND OF THE INVENTION

Conveying thin, planar, flexible work pieces through a work station often requires that the work piece be maintained in a perfectly flat condition. Although this can often be done with hold-down devices such as rollers, the use of rollers or other devices that contact the surface of the work piece is not always permitted or desirable. Also, a vacuum applied to the underside of the work piece could be used but is not always practical due to the working environment or other factors.

Although the present invention is applicable to various thin, planar, flexible work pieces and various types of work stations, it is particularly applicable to lithographic printing plates which have been imaged and require development to remove the areas of the coating on the plate which have been rendered soluble by the imaging process. In conjunction with the issue of conveying an imaged lithographic printing plate through a development work station, there are other related issues regarding the storage and application of the developer solution. Therefore, these issues will be discussed in the further description of the background of the invention and the later description of the preferred embodiments of the invention even though the broadest aspects of the invention are not limited in this respect.

The usual method for development of positive-working imaged lithographic printing plates entails immersion in an alkaline developing solution. This is most often done in a plate processor that contains a reservoir or sump of the developing solution. Developer from this reservoir is circulated through the developing tank of the processor where it comes in contact with the imaged plate. The alkalinity of the developer must be maintained at the correct level. If the pH of the developer is too low, the imaged coating will not be completely removed. If the pH of the developer is too high, it will dissolve the coating in the non-imaged areas.

This development process suffers from several drawbacks. Exposure of the developer to the atmosphere causes a decrease in alkalinity as a result of carbon dioxide absorption. The alkalinity of the reservoir will thus vary with the age of the developer. As plates are developed, the alkalinity of the developer declines, and the reservoir must be replenished with appropriate replenishing developer solution at a managed rate. Conductivity meters are most often used to manage the developer activity. However, these do not directly measure alkalinity, and may not be adequate to achieve a tight control on developer activity. The activity of the developer will also vary with the amount of dissolved coating contained in the developer which will also affect the viscosity. The development of the plates relies on the ability of the alkaline developer to percolate or dissolve into the coating. The presence of the dissolved coating in the developer will alter the rate of percolation or dissolution. Thus plates processed with a fresh developer solution do not develop at the same rate as plates processed with developers that contain substantial levels of dissolved coating.

Another method for the development of the imaged plates entails the application of a thin film or layer of developing solution to the imaged plate surface of each imaged plate to be developed. This thin film of developer solution is allowed to dwell on the plate for a time sufficient to complete the development and then rinsed from the plate. Because only a thin film of developer solution is applied to each plate, any variation of any part of the surface of the plate from flat and horizontal can result in the improper development of the coating. Since the plates are thin and flexible, it is essential that steps be taken and means be provided to maintain the plate in such a position.

Usually the rinsed developer is sent to waste and fresh developer is used for each plate. This is sometimes referred to as a sumpless system. Although this method does not have the problem with dissolved coating material in the developer solution because fresh developer is used each time, the supply of developer solution is still subject to decreases in alkalinity.

### SUMMARY OF THE INVENTION

The present invention is directed to a system and method for conveying a thin, planar, flexible workpiece through a work station in a flat, horizontal position. The invention is specifically directed to improvements in a system and method for developing lithographic printing plates wherein a thin film of developer solution is applied to each plate. The invention includes a method and apparatus for conveying the plates through the developer in a flat, horizontal orientation such that the thin film of developer is uniformly distributed over the plate surface. The imaged plate is delivered to a continuous conveyor belt moving across a flat, horizontal platen where the thin layer of developing solution is applied. The developer is allowed to dwell on the plate as it is conveyed across the platen for a sufficient time to allow for percolation into and/or dissolution of the soluble areas of the coating. The developer with the dissolved coating is then rinsed from the plate. In the preferred embodiment, the plate is maintained flat and in position on the conveyor belt by means of the surface tension provided by a film of water on the conveyor belt. It is also preferred that the conveyor belt be textured to retain the water film. Also in the preferred form of the invention, the spent developer rinsed from the plate is sent to waste and fresh developer solution is applied to each plate. The invention also involves an anaerobic system for storing and delivering upon demand the fresh developer solution whereby the fresh developer solution is isolated from the atmosphere.

### BRIEF DESCRIPTION OF THE DRAWINGS

FIG. 1 is a diagrammatic sketch of a lithographic printing plate developer apparatus for practicing the invention.

FIG. 2 is a diagram of a developer solution supply system incorporating an air-tight bladder.

### DESCRIPTION OF THE PREFERRED EMBODIMENTS

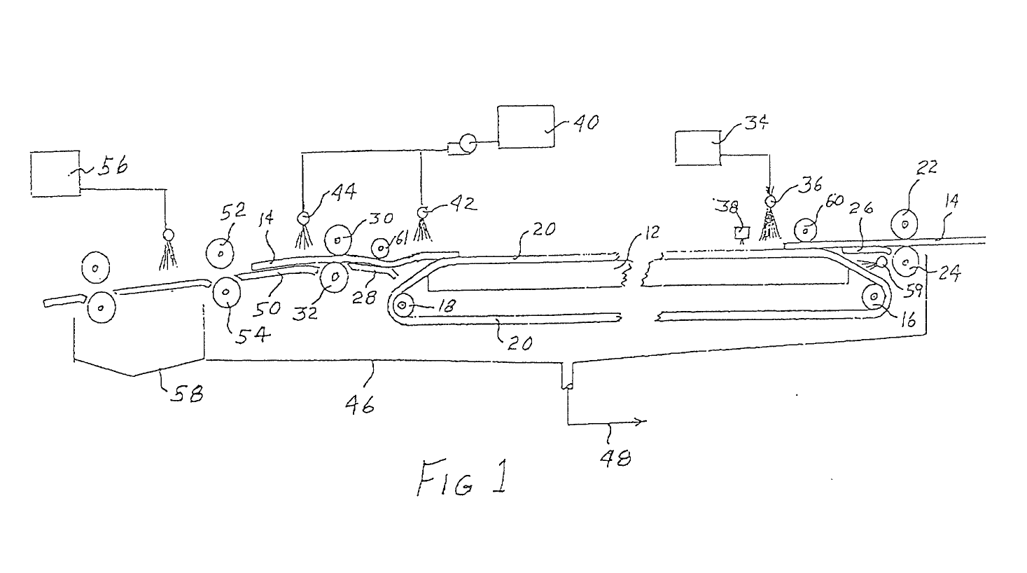

FIG. 1 is a diagrammatic drawing illustrating the general arrangement of the preferred equipment for practicing the invention as well as illustrating the method of developing the imaged lithographic printing plates. The developer comprises a platen 12 which may be any flat, horizontal surface composed of materials which will be unaffected by the particular developer solution to be used. The printing plate 14, which has been exposed and thus imaged, is carried across the platen 12 by means of a conveyor which comprises the conveyor drive rollers 16 and 18 and a continuous flexible conveyor belt 20. The conveyor belt 20 is composed of a material which will be unaffected by the developer solution, such as stainless steel or a plastic material. The preferred nature of the conveyor belt 20 will be discussed later. The printing plate 14 is fed by the feed rollers 22 and 24 onto the feed platform 26 which directs the printing plate onto the conveyor belt 20 for transport across the platen 12. After processing, the printing plate is guided by the discharge platform 28 into a pair of discharge rollers 30 and 32.

The printing plate 14 as delivered to the developer has been exposed to an imaging process. As is well known in the art, the imaging radiation renders the imageable coating soluble in the imaged areas of a positive working plate and renders the imageable coating insoluble in the imaged areas of a negative working plate. In either case, it is the coating which has been rendered soluble or the coating which has remained soluble that is removed in the development process of the present invention. The particular compositions of the developer solutions for these different types of printing plates are well known. For example, many of the printing plates currently in use have coatings that contain alkali-soluble resins, specifically phenolic or acrylic resins. As stated earlier, these coatings usually contain dissolution inhibitors that render them insoluble in the alkaline developers. The imaging process reverses this dissolution inhibition and the coating then becomes soluble in the areas subjected to the imaging radiation.

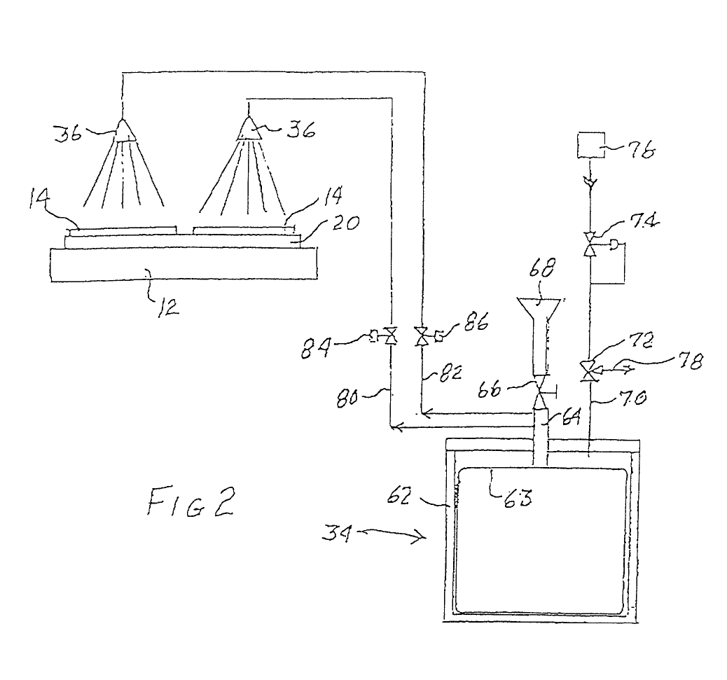

At the beginning of the travel of the printing plate across the platen 12, the printing plate is sprayed with developer solution. The developer solution is fed from the supply tank 34 to one or more spray nozzles 36 which are appropriately designed and located to spread the developer solution generally uniformly over the surface of the printing plate as it is being conveyed. The details of the developer supply will be discussed later in conjunction with FIG. 2. The developer solution will inherently flow on its own across the plate and tend to form a uniform layer of developer solution. If needed, the developer solution can be spread by a Meyer-Rod coater or a knife edge coater generally indicated at 38. The quantity of developer solution needed is generally only that quantity needed to form a thin film of developer solution generally 2 to 10 mils thick. However, the specific quantity needed will vary and be determined by the particular nature of the coating to be dissolved and the nature of the developer solution.

The printing plate which has been sprayed with the developer solution continues to travel across the platen. The length and speed of travel is selected such that the developer solution will have completed the development process by the time the printing plate reaches the discharge end of the platen. A typical development time is 20 to 60 seconds. At this point, rinse water from the supply 40 is sprayed onto the plate through the spray nozzles 42 and 44. Located below the conveyor structure is a collection pan 46 which collects all of the liquid run off from the printing plate including any excess developer solution and the spent developer solution and rinse water now containing the portion of the coating which has been dissolved away. Although the developer solution which is rinsed from the plate could be recycled and used again in a system incorporating certain other features of the invention, the collected liquid is preferably sent to waste at 48. In that case, it can be seen that there is always only fresh developer solution being applied to the plates and that there is only a small quantity of developer solution applied to each plate. It has been discovered that the consumption of developer solution can be reduced by as much as 50% when compared to a conventional printing plate development processor. As an option, the dissolved coating may be vacuumed from the plate. From the rinse section of the developer, the plate may be fed across the platform 50 and into the feed rollers 52 and 54 and delivered to a finishing section where the developed and rinsed plate is treated in any conventional manner such as with gum arabic from the tank 56. The excess gum arabic or other treating material is collected in the tray 58 and then probably recycled. Following the finishing section there may be a dryer.

Some imaged coatings are not totally soluble in the developer solution. That is, although the basic coatings are soluble, the coatings may contain components which are not soluble. For example, negative-working coatings contain dyes or pigments which are not soluble that remain as small particles. In order to assure that these particles are removed from the plate and carried away as part of the spent developer solution, a device may be included to apply some mechanical action or forces to the developed coating. This may take the form of a roller 61 which, for example, may be a light brush or a cloth roller often referred to as a molleton roller. Spray nozzle 42 may optionally be positioned to spray directly onto the brush/molleton roller 61, or immediately after roller 61 in addition to the location shown in FIG. 1.

In order to properly develop an imaged plate in accordance with the present invention, it is essential that the thin film of developer solution be substantially uniformly distributed over the entire upper, imaged surface of the plate as it is being conveyed across the platen. This requires that the plate on the conveyor be flat and horizontal or level and begins with having a flat, horizontal platen and, therefore, a flat horizontal conveyor belt. Since the printing plates are very thin and flexible, it also requires a method for maintaining the plate in position and flat on the conveyor belt. For this aspect of the invention, surface tension is used to hold the plate firmly in position and flat on the conveyor belt. This is done by providing a film of water between the plate and the conveyor belt. In the preferred embodiment, the conveyor belt 20 has an outside surface which is textured to hold water as the conveyor belt circulates around its path. Therefore, the film of water is in place on the conveyor belt as the plate is fed onto the conveyor belt. The water is primarily provided by the rinse water which impinges on the conveyor belt. In addition, a water spray nozzle 59 may be provided just before the plate is fed onto the conveyor belt if needed to ensure a properly wetted conveyor belt. Also, to assure that the plate is initially flat as it is fed onto the belt, a hold down roller 60 is provided. As can be seen, there are no additional hold down rollers or drive rollers contacting the plate as it moves across the platen and is being developed.

As indicated, it is desired that the outer surface of the conveyor belt be textured specifically to hold water. In the most preferred embodiment, the conveyor belt 20 is a plastic belt, preferably polyvinyl chloride (PVC) with a smooth inner surface and a textured outer surface. The textured outer surface has small pockets or interstices which retain water by surface tension as the belt rotates around the conveyor path. This textured surface may be formed from a woven fiberglass mat which is adhered to the belt backing with a resin. The water is retained in the openings in the fiberglass mat and it has been found that there is a very strong bond formed by the surface tension between the plate and the conveyor belt.

As indicated in the background of this invention, one of the factors which affects alkaline developer solutions is exposure to the atmosphere which causes a decrease in alkalinity as a result of carbon dioxide absorption. FIG. 2 illustrates an embodiment of the invention which is designed to prevent or minimize the exposure of the developer solution to the atmosphere at least in the supply tank 34. This FIG. 2 also illustrates an embodiment of the invention in which the developing system is adapted to process a plurality of plates 14 side-by-side on the conveyor belt 20. First, with respect to this latter feature, the platen 12 and the conveyor belt 20 are wide enough to provide two paths for conveying plates through the developer system. Furthermore, the plates can be sent through either simultaneously or at different intervals. To accommodate that feature, there are two separate developer spray nozzles 36, one for each path, which may be separately actuated as will be explained in connection with the developer supply system. Merely as one example, the conveyor belt may be wide enough to accommodate plates up to 32 inches wide or two parallel plates with a combined width of 32 inches. Assuming plates up to 30 inches long may be processed and assuming a conveyor belt operating speed up to 5 feet per minute, plates can be fed to the developer at the rate of one every thirty seconds per path. Of course, the conveyor structure of the present invention can be any length desired. Therefore, since there are no drive rollers which would need to be spaced to contact various length plates to drive them through the developer, plates of any length can now be processed.

The system for storing the fresh developer solution and delivering it to the spray nozzle 36 is an anaerobic system. That is, there is no contact of the developer solution with air even though compressed air may be used to drive the developer solution from the supply tank to the spray nozzles. The developer supply tank 34 comprises an airtight pressure enclosure 62 which contains a flexible bladder 63 preferably made of nitrile rubber. Attached to the bladder 63 is the developer supply line 64 which extends through the pressure enclosure 62 and through the fill valve 66 to the filler funnel 68. Also extending through the enclosure 62 is the pressure line 70 which terminates inside of the enclosure 60 but outside of the bladder 63. This line is connected through a three-way valve 72 and a pressure regulating valve 74 to a source of pressure which is preferably an air pressure supply 76. However, the pressure supply could be any pneumatic or hydraulic fluid. During the filling of the bladder with developer solution, the valve 66 is opened and the three-way valve 72 is opened to the atmosphere at 78 and closed to the air supply 76. The bladder is then filled which expels the air from the enclosure 62. The valves are then reversed so that the air will put pressure on the bladder so that the developer solution can be forced up into the supply line 64 and out of the two spray supply lines 80 and 82. These lines 80 and 82 are connected to the spray nozzles 36 through the solenoid valves 84 and 86. Since the pressurizing air is only in the airtight enclosure 62 on the outside of the flexible bladder 63, there is no contact between the pressurizing air and the developer solution. Likewise, there is no contact with air in the spray supply lines 80 and 82. Therefore, there is no chance for the air to alter the developer solution chemistry or for air bubbles to be entrained in the developer solution.

As can be seen from the foregoing description of the invention, there are a number of unique features and resulting advantages as follows:

a) the work piece is held flat on the conveyor by surface tension thereby eliminating any hold-down devices such as rollers from contacting the work piece.

b) there are no hold-down devices that would require certain preset spacings, there are no limitations on the length of the work piece that can be accommodated by the transport system.

c) fresh developer solution is preferably used for each plate.

d) the developer solution is protected from degradation by contact with air in the storage and delivery system.

e) no drive wheels or rollers contact the coating during development.

f) the conveyor can be dimensioned to accommodate any length plate.

g) the plates are held flat on the conveyor belt by surface tension.

1. A method of developing a lithographic printing plate having an imaged coating thereon comprising areas of coating insoluble in a selected developer solution and areas of coating soluble in said selected developer solution in order to remove said soluble coating comprising:
a. applying fresh selected developer solution to said imaged coating on said plate;
b. conveying said plate with said selected developer solution on said imaged coating across a flat horizontal platen over a period of time during which said soluble coating dissolves in said developer solution and produces a spent developer solution and a developed plate; and
c. removing said spent developer solution from said developed plate.

2. A method as recited in claim 1 and further comprising the step of repeating steps a to c for successive plates.

3. A method as recited in claim 1 wherein said step of conveying said plate across a flat horizontal platen comprises placing said plate on a continuous conveyor belt moving across said platen with a film of liquid between said conveyor belt and said plate whereby said plate is held in position and flat on said conveyor belt by surface tension.

4. A method as recited in claim 3 wherein said film of liquid comprises water and wherein said step of placing said plate on said conveyor belt further includes the step of applying water between said conveyor belt and said plate.

5. A method as recited in claim 3 wherein said step of removing said spent developer solution comprises the step of rinsing said spent developer solution from said developed plate with rinse water and wherein said conveyor belt carries a film of rinse water which comprises at least a portion of said film of liquid.

6. A method as recited in claim 5 wherein said step of placing said plate on said conveyor belt further includes the step of applying additional water between said conveyor belt and said plate.

7. A method as recited in claim 1 wherein said step of removing said spent developer solution further includes the steps of collecting and discharging said spent developer solution to waste.

8. A method of developing lithographic printing plates having an imaged coating thereon comprising areas of coating insoluble in a selected developer solution and areas of coating soluble in said selected developer solution in order to remove said soluble coating comprising the steps of:
a. conveying said plate having said imaged coating thereon into a developer station;
b. applying a thin film of fresh selected developer solution to said imaged coating;
c. conveying said plate with said thin film of fresh selected developer solution across a flat horizontal platen for a period of time sufficient for said soluble coating to dissolve in said developer solution and produce a spent developer solution and a developed plate;
d. removing said spent developer solution from said developed plate;
e. conveying said plate out of said developer station; and
f. repeating steps a to e for successive printing plates.

9. A method as recited in claim 8 wherein said step of removing said spent developer solution comprises the step of rinsing said spent developer solution from said developed plate with rinse water and collecting and discharging said spent developer solution to waste.

10. A method as recited in claim 8 wherein said step of applying a thin film of fresh selected developer solution comprises spraying said fresh selected developer solution onto said imaged coating.

11. A method as recited in claim 10 and further including the step of spreading said sprayed fresh selected developer solution evenly over said coating.

12. A method as recited in claim 8 wherein said step of conveying said plate across a flat horizontal platen comprises placing said plate on a continuous conveyor belt moving across said platen and applying a film of liquid between said conveyor belt and said plate whereby said plate is held in position and flat on said conveyor belt by surface tension.

13. A method as recited in claim 12 wherein step of removing said spent developer solution comprises the step of rinsing said spent developer solution from said developed plate with rinse water and wherein said conveyor belt carries a film of rinse water which comprises at least a portion of said film of liquid.

14. A method as recited in claim 13 wherein said step of placing said plate on said conveyor belt further includes the step of applying additional water between said conveyor belt and said plate.

15. A method of developing a lithographic printing plate having an imaged coating thereon comprising areas of coating soluble in a selected developer solution and areas insoluble in said selected developer solution in order to remove said soluble coating comprising:
a. feeding said plate onto a continuous conveyor belt containing a film of liquid between said plate and said conveyor belt whereby said plate is held flat on said conveyor belt by surface tension;
b. applying a selected developer solution to said imaged coating;
c. conveying said plate on said conveyor belt across a flat horizontal platen for a period of time sufficient for said soluble coating to dissolve in said developer solution and produce a developed plate; and
d. removing said developer solution from said developed plate.

16. A method as recited in claim 15 wherein said step of removing said developer solution comprises spraying said developed plate with rinse water and wherein at least a portion of said film of liquid between said conveyor belt and said plate comprises rinse water retained on said conveyor belt.

17. A method as recited in claim 16 wherein said step of feeding said plate onto said conveyor belt further includes the step of spraying additional water between said conveyor belt and said plate.

18. Apparatus for developing a lithographic printing plate having an imaged coating on a surface thereof comprising areas of coating insoluble in a selected developer solution and areas of coating soluble in said selected developer solution, said apparatus adapted to remove said soluble coating from said plate and comprising:
a. means for conveying said plate through said apparatus comprising a flat horizontal platen and a conveyor belt for moving said plate across said platen;
b. means for applying developer solution to said imaged coating on said surface for a period of time necessary for said soluble coating to dissolve in said developer solution and produce a spent developer solution and a developed plate; and
c. means for removing said spent developer solution from said developed plate.

19. Apparatus as recited in claim 18 and further including means for discharging said spent developer solution to waste.

20. Apparatus as recited in claim 18 wherein said means for applying developer solution comprises means for spraying said developer solution onto said surface of a plate on said conveyor belt.

21. Apparatus as recited in claim 20 and further including means for spreading said sprayed developer solution over said surface.

22. Apparatus as recited in claim 18 wherein said means for removing said spent developer solution from said developed plate comprises means for rinsing said spent developer solution therefrom.

23. Apparatus as recited in claim 18 including means for storing said developer solution for application to said imaged coating comprising means for preventing exposure of said developer solution to the atmosphere.

24. Apparatus as recited in claim 23 wherein said means for preventing exposure comprises a flexible bladder.

25. Apparatus as recited in claim 24 including means for applying pressure to the outside of said flexible bladder to force said developer solution stored therein onto said imaged coating.

26. Apparatus as recited in claim 25 wherein said means for applying pressure comprises means for applying air pressure.

27. Apparatus as recited in claim 18 including means for storing said developer solution and delivering said developer solution to said imaged coating comprising:
a. an airtight pressure enclosure;
b. a flexible bladder inside of said enclosure for containing said developer solution;
c. means for conducting said developer solution from said flexible bladder to said imaged coating;
d. means for applying pressure to the inside of said enclosure and the outside of said flexible bladder to force said developer solution from said flexible bladder through said conducting means.

28. Apparatus as recited in claim 27 wherein said means for applying pressure comprises means for applying air pressure.

29. Apparatus as recited in claim 18 wherein said conveyor belt comprises a solid flexible backing and a woven fiberglass mat adhered to the face thereof.

30. Apparatus for developing a lithographic printing plate having an imaged coating on a surface thereof comprising areas of coating insoluble in a selected developer solution and areas soluble in said selected developer solution, said apparatus adapted to remove said soluble coating from said plate and comprising:
a. a flat horizontal platen;
b. means for conveying said plate through said apparatus comprising a conveyor belt for moving said plate across said platen;
c. means for applying a layer of said developer solution to said imaged coating on said surface for a period of time necessary for said soluble coating to dissolve in said developer solution and produce a developed plate; and
d. means for applying a film of liquid between said conveyor belt and said plate whereby said plate is held in position and flat on said conveyor belt by surface tension.

31. Apparatus as recited in claim 30 and further including means for removing said developer solution from said developed plate and discharging said developer solution to waste.

32. Apparatus as recited in claim 31 wherein said means for removing said developer solution from said developed plate comprises means for rinsing said developer solution therefrom.

33. Apparatus for applying fresh developer solution to an imaged coating on the surface of a lithographic printing plate comprising:
a. means for storing said fresh developer solution including means for preventing exposure of said fresh developer solution to the atmosphere;
b. means for applying said fresh developer solution to an imaged coating; and
c. means for delivering said fresh developer solution without atmospheric exposure from said storage means to said means for applying said fresh developer solution.

34. Apparatus for applying a fresh developer solution to an imaged coating on the surface of a lithographic printing plate comprising means for storing and delivering fresh developer solution to an imaged coating comprising:
a. an airtight pressure enclosure;
b. a flexible bladder inside of said enclosure for containing said fresh developer solution;
c. means for applying said fresh developer solution to said imaged coating;
d. flow means connecting said flexible bladder to said means for applying said fresh developer solution;
e. means for applying pressure to the inside of said enclosure and the outside of said flexible bladder to force said fresh developer solution from said flexible bladder through said flow means to said means for applying said fresh developer solution.

35. Apparatus as recited in claim 34 wherein said means for applying pressure comprises means for applying air pressure.

36. A method for conveying a thin, planar, flexible work piece through a work station in a flat horizontal position comprising the steps of:
a. feeding said work piece onto a continuous conveyor belt and applying a film of liquid between said work piece and said conveyor belt whereby said work piece is held flat on said conveyor belt by surface tension; and
b. conveying said work piece on said conveyor belt across a flat, horizontal platen.

37. Apparatus for conveying a thin, planar, flexible work piece through a work station comprising:
a. a flat horizontal platen located in said work station;
b. a continuous conveyor belt for conveying said work piece across said platen and through said work station; and
c. means for applying a film of liquid between said conveyor belt and said work piece for holding said work piece in position and flat on said conveyor belt by surface tension.

38. Apparatus as recited in claim 37 wherein said conveyor belt comprises a solid flexible backing and a woven fiberglass mat adhered to the face thereof.
